(19) United States
(12) Patent Application Publication
(10) Pub. No.: US 2009/0166665 A1
(43) Pub. Date: Jul. 2, 2009

(54) Encapsulated optoelectronic device

(75) Inventor: Deborah Ann Haitko, Schenectady, NY (US)

Correspondence Address: Fay Sharpe LLP, 1228 Euclid Avenue, 5th Floor, The Halle Building, Cleveland, OH, 44115, US

(73) Assignee: Lumination LLC

(21) Appl. No.: 12/006,167

(22) Filed: Dec. 31, 2007

(51) Int. Cl. H01L 33/00

(52) U.S. Cl. 257/100; 438/26; 257/E33.059

(57) ABSTRACT

The invention provides an optoelectronic device (e.g. a LED device) and method thereof. The device includes an optoelectronic component at least partially surrounded by an encapsulant comprising a silicone such as an aliphatic silicone and an adhesion promoter. The optoelectronic device exhibits improved properties such as adhesion and structural integrity, UV and thermal stability, and long term stability under accelerated aging conditions.

### BACKGROUND OF THE INVENTION

The present invention is generally related to an optoelectronic device and method thereof. The invention can be broadly applied in general illumination, lighting for signals and automobiles, and backlighting for LCDs and displays etc. More particularly, the device can be for example a LED device that includes an encapsulant comprising a silicone such as an aliphatic silicone and an adhesion promoter.

The fabrication of an optoelectronic device depends heavily upon the structural integrity of its various components. For instance, the bonding strength between encapsulant and optoelectronic device is important for the duration, reliability, the integrity, and performance of the device. Transparent epoxy resins such as bisphenol A epoxy resin and acyclic epoxy resin have been used as the encapsulating material for an optoelectronic device. However, they have drawbacks including poor durability to moisture due to high percent water absorption, poor durability to light, low transmittance to short wavelength light, and coloring due to photo degradation. Moreover, with a high modulus of elasticity, epoxy resins may be distorted during temperature cycling because of the different coefficients of linear expansion for the wire, the chip, and the epoxy resin. The generated stress acts on the wire bonding, and as a result, cracks can occur in the encapsulant, disconnecting the wire bonding. As a result of the stress applied by the epoxy resin to the LED chip, there is a danger of the crystal structure of the LED chip being destroyed, decreasing the luminous efficiency of the LED.

Silicone has been used as an alternative material for the encapsulation. Compared with the epoxy resin, a silicone material exhibits superior heat resistance, weather resistance, light stability, color fastness, and the like. The light-transmitting property of the silicone material does not degrade easily over time, so that the silicone material does not develop a yellowish color easily. For example, phenyl-containing silicones degrade after exposure to UV LED greater than 2000 hours. However, the best silicones to date are those that contain a mix of methyl and phenyl groups. Methyl and phenyl blend-containing silicones nonetheless show slightly poor adhesiveness to the lead frame and the substrate on which the light-emitting element is mounted. Poor adhesion can affect the optical integrity of the LED, and the end result is inconsistent illumination or no illumination from all or part of an LED.

U.S. Pat. No. 6,762,113 discloses a method for coating a semiconductor substrate with a mixture containing an adhesion promoter. The method uses a coating mixture of an α-amino propyltriethoxysilane in organic solution and a photopolymer material with mercapto-ester in solution.

The present invention advantageously provides an optoelectronic device, such as an LED device, having improved properties such as adhesion and structural integrity, UV and thermal stability, and long term stability under accelerated aging conditions (e.g. >5,000 hours).

### BRIEF DESCRIPTION OF THE INVENTION

One aspect of the present invention is an optoelectronic device, such as an LED device, including an optoelectronic component and an encapsulant wherein the encapsulant comprises a silicone such as an aliphatic silicone and an adhesion promoter. The optoelectronic component is at least partially surrounded by the encapsulant.

Another aspect of the invention is a method of constructing an optoelectronic device such as a LED device comprising: (a) providing an optoelectronic component; and (b) applying an encapsulant comprising a silicone such as an aliphatic silicone and an adhesion promoter onto or around the optoelectronic component.

### BRIEF DESCRIPTION OF THE DRAWINGS

FIG. 1 shows a schematic diagram of an LED device according to an embodiment of the present invention;

FIG. 2 shows a schematic diagram of an LED array on a substrate according to one embodiment of the present invention;

FIG. 3 shows a schematic diagram of an LED device according to another embodiment of the present invention;

FIG. 4 shows a schematic diagram of a vertical cavity surface emitting laser device according to still another embodiment of the present invention;

FIG. 5 shows the results of five die shear test measurements for five adhesion promoters against GETOS 9142 with varying ratio of 0.5, 1.0, 1.5 2.0 and 3.0% in weight;

FIG. 6 shows the results of five die shear test measurements for five adhesion promoters against NYE OCK 451 with varying ratio of 0.5, 1.0, 1.5 2.0 and 3.0% in weight;

FIG. 7 shows the transmittance change of GE Toshiba GETOS 9142 and NYE OCK 451 with adhesion promoters over aging time at 125° C.;

FIG. 8 shows the transmittance changes of GETOS 9142 silicone with aging time for different adhesion promoters with different level;

FIG. 9 shows the transmittance changes of NYE OCK 451 silicone with aging time for different adhesion promoters with different level;

FIG. 10 shows the thermal aging of NYE OCK 451 with 2-(3,4-epoxy cyclohexyl)ethyl-trimethoxysilane at 85 and 125° C.;

FIG. 11 shows the thermal aging of NYE OCK 451 with (3-glycidyloxypropyl)trimethoxysilane at 85 and 125° C.; and

FIG. 12 shows the results of five die shear test measurements for five adhesion promoters against GE RTV 615 and 656 with varying ratio of 0.5, 1.0, 1.5 2.0 and 3.0% in weight.

### DETAILED DESCRIPTION OF THE INVENTION

Any optoelectronic device that benefits from encapsulation may benefit from the present invention. Exemplary optoelectronic devices include, but are not limited to, light emitting diodes (LEDs) and arrays thereof, charge coupled devices (CCDs), large scale integrations (LSIs), photodiodes, laser diodes, vertical cavity surface emitting lasers (VCSELs), phototransistors, photocouplers, and optoelectronic couplers etc.

It should be understood that the words “encapsulation” and “encapsulant” etc. used in the present description covers various embodiments in which the optoelectronic components are encapsulated to not only a traditional cannonball shape, but also any shape that is adapted to devices of the “surface mount” variety.

An optoelectronic device typically comprises many components that are made from a wide variety of organic or inorganic materials. For example, the optoelectronic components may include semiconductor chip, LED lens, lead frame, bond wire, solder, electrode, pad, contact layer, phosphor layer, dielectric layer, receptacle, silver substrate, and electrical board such as a Bergquist board housing a chip. These optoelectronic components may be made of or made from materials, for example, metals such as aluminum, gold, silver, tin-lead, nickel, copper, and iron, and their alloys; silicon; passivation coatings such as silicon dioxide and silicon nitride; aluminum nitride; alumina; fluorocarbon polymers such as polytetrafluoroethylene and polyvinylfluoride; polyamides such as Nylon; organic resins such as polyimide; silicones; epoxy resin; polyesters; ceramics; plastic; and glass etc.

Taking a LED chip as an illustrative example, it may contain any desired Group III-V compound semiconductor layers, such as GaAs, GaAlAs, GaN, InGaN, GaP etc., or Group II-VI compound semiconductor layers such as ZnSe, ZnSSe, CdTe, etc., or Group IV-IV semiconductor layers, such as SiC.

The phosphor layer or coating, as another illustrative example, may be cerium-doped yittrium aluminum oxide Y₃Al₅O₁₂ garnet (“YAG:Ce”). Other suitable phosphors are based on YAG doped with more than one type of rare earth ions, such as (Y_{1-x-y}GdₓCe_{y})₃Al₅O₁₂ (“YAG:Gd,Ce”), (Y₁₋ₓCeₓ)₃(Al_{5-y}Ga_{y})O₁₂ (“YAG:Ga,Ce”), (Y_{1-x-y}GdₓCe_{y})(Al_{5-z}Ga_{z})O₁₂ (“YAG:Gd,Ga,Ce”), and (Gd₁₋ₓCeₓ)Sc₂Al₃O₁₂ (“GSAG”), where 0≦x≦1, 0≦y≦1, 0≦z≦5, and x+y≦1. Related phosphors include Lu₃Al₅O₁₂ and Tb₂Al₅O₁₂, both doped with cerium. In addition, these cerium-doped garnet phosphors may also be additionally doped with small amounts of Pr (such as about 0.1-2 mole percent) to produce an additional enhancement of red emission. Non-limiting examples of phosphors that are efficiently excited by radiation of 300 nm to about 500 nm include green-emitting phosphors such as Ca₈Mg(SiO₄)₄Cl₂:Eu²⁺, Mn²⁺; GdBO₃:Ce³⁺, Tb³⁺; CeMgAl₁₁O₁₉:Tb³⁺; Y₂SiO₅:Ce³⁺, Tb³⁺; and BaMg₂Al₁₆O₂₇:Eu²⁺, Mn²⁺ etc.; red-emitting phosphors such as Y₂O₃:Bi³⁺,Eu³⁺; Sr₂P₂O₇: Eu²⁺, Mn²⁺; SrMgP₂O₇:Eu²⁺, Mn²⁺; (Y,Gd)(V,B)O₄:Eu³⁺; and 3.5MgO.0.5MgF₂.GeO₂:Mn⁴⁺ (magnesium fluorogermanate) etc.; blue-emitting phosphors such as BaMg₂Al₁₆O₂₇:Eu²⁺; Sr₅(PO₄)₁₀Cl₂:Eu²⁺; (Ba,Ca,Sr)(PO₄)₁₀(Cl,F)₂:Eu²⁺; and (Ca,Ba,Sr)(Al,Ga)₂S₄:Eu²⁺ etc.; and yellow-emitting phosphors such as (Ba,Ca,Sr)(PO₄)₁₀(Cl,F)₂:Eu²⁺,Mn²⁺ etc.

One or more of the aforementioned optoelectronic components are at least partially surrounded by an encapsulant comprising a silicone such as an aliphatic silicone and an adhesion promoter. In an embodiment, the encapsulant functions as an optical element and/or protective shell. The encapsulant may comprise aliphatic silicone, copolymer of aliphatic silicone and other polymer such as epoxy resin, or copolymer of aliphatic silicone and aromatic silicone, or mixture thereof.

Preferred silicones are a synthetic polymer containing a Si—O—Si backbone, in which the silicon atoms bear mainly aliphatic groups in addition to the —O— bridges, and in some examples, —CH₂CH₂— bridges, between two neighboring silicon atoms. The term “mainly aliphatic groups” means that the silicone contains no aromatic groups such as phenyl group, or may contain a minimal amount of aromatic groups to the extent that they do not deteriorate the benefits that the aliphatic silicone is designed to give.

In a variety of exemplary embodiments, the aliphatic group is selected from alkyl groups, such as C₁-C₆ alkyl groups. In preferred embodiments, the aliphatic group is a methyl group.

Addition or condensation reaction can be employed to cure the silicone. However, addition curing is preferred because it can proceed as rapidly as possible; it does not need to remove the by-products such as alcohols; and the reaction progresses quantitatively. Preferably, the addition curing can be conducted at room temperature or under elevated temperature conditions.

The silicone such can be prepared from room temperature vulcanizing (RTV) silicone systems. RTV silicones usually come as uncured rubbers with liquid or paste-like consistencies, and are used for sealants, mould making, encapsulation and potting. RTV curing is based on chemical reactions that provide cross-linking and increase molecular weights, e.g. hydrosilylation, preferably in the presence of catalysts to ensure cure control.

The silicone can be prepared from a RTV-2 silicone system. The curing of RTV-2 silicones may be triggered by mixing together two separate components (part A and part B), preferably one of which contains a catalyst such as a hydrosilylation catalyst, e.g. Pt catalyst.

The silicone may be prepared by intimately mixing the two parts. Most often, the two parts are stored separately so as to prohibit the progress of cure. On use, two parts are mixed together whereupon cure takes place. It should be understood that one can formulate a one-part composition by adding minor amounts of reaction inhibitors such as acetylene alcohol compounds, triazoles, nitrile compounds or phosphorus compounds to the composition for extending the pot-life.

Part A and part B components of the RTV-2 may be mixed according to a desired mix ratio. With clean tools, one may thoroughly mix the ingredients together, scraping the sides and bottom of the container carefully to produce a homogeneous mixture. When using power mixers, an operator should avoid excessive speeds which could entrap large amounts of air, or cause overheating of the mixture, resulting in shorter pot life. Air entrapped during mixing should be removed to eliminate voids in the cured product. The mixed material may be exposed to a vacuum of about 25 mm (29 in.) of mercury. The material will typically expand, crest, and recede to approximately the original level as the bubbles break. Degassing is usually complete approximately two minutes after frothing ceases. For potting, a deaeration step may be necessary after pouring to avoid capturing air in complex assemblies. In some embodiments, automatic equipment designed to meter, mix, deaerate, and dispense the composition of the present invention will add convenience to continuous or large volume operations.

Cure temperature for the RTV silicone is in the range of about 50° C. to about 160° C., preferably in the range of about 80° C. to about 155° C. Cure through time or cure time may be in the range of about 0.1 hours to about 4 hours, preferably in the range of about 0.5 hours to about 3 hours and most preferably in the range of about 1 hour to about 2 hours.

The viscosity of a fluid is its resistance to shear or flow and is a measure of the fluids adhesive/cohesive or frictional properties. The resistance is caused by intermolecular friction exerted when layers of fluids attempts to slide by another. There are many ways to measure viscosity and consequently many ways to express it, for example, CentiStokes (cSt), CentiPoises (cP), Saybolt Universal Seconds (SSU) and degree Engler. A skilled person knows how to convert one viscosity unit to another, for example, CentiPoises (cp)=CentiStokes (cSt)×Density. In typical embodiments of the invention, the RTV silicone may have a viscosity (@ 25° C., uncured and mixed) in the range of about 3500 to about 4500 cps.

Other properties of the cured RTV silicone may include, for example, a thermal expansion in the range of about 20-35×10⁻⁵ (C)⁻¹; a thermal conductivity in the range of about 0.18 to about 0.2 W/m·° K.; and any other suitable properties such as brittle point, hardness, tensile strength, elongation, volume resistivity, dielectric strength, and dielectric constant etc.

The RTV-2 silicone system will normally cure in contact with the surface of the optoelectronic components as described above, in the presence of the adhesion promoter. However, it should be noted that certain materials, such as butyl and chlorinated rubber, sulfur-containing materials, amines, and certain metal soap-cured RTV silicone rubber compounds, can cause cure inhibition. Cure inhibition is characterized by a gummy appearance of the RTV silicone rubber compound at the interface between it and the substrate.

Specific examples of RTV-2 silicone materials include, but are not limited to, RTV 615 and RTV 656 or 655 from General Electric Silicones (now known as Momentive).

GE RTV 615 is clear and dispensed easily and may be used as silicone rubber compound for electronic potting with optical clarity allowing maximum light transmission, and also protecting electronic components against shock, moisture, and other environmental hazards. RTV 615 comprises polydimethylsiloxane bearing vinyl groups and a platinum catalyst (Part A) and a cross-linker containing silicon hydride (Si—H) groups (Part B) which form a covalent bond with vinyl groups. RTV 615 normally comprises Part A and Part B in a weight ratio of 10:1 (Part A:Part B).

Optionally, a primer may be used when RTV-2 silicone system is applied on a non-silicone substrate. For example, SS4120 primer (RTV 615-1P) may be used with RTV 615, and SS4155 primer may be used with RTV 656. Non-silicone surface may be thoroughly cleaned with a non-oily solvent such as naphtha or methyl ethyl ketone and allow to dry. Then apply a uniform thin film of silicone primer and allow the primer to air dry for one hour or more. Finally, apply freshly catalyzed mixture of RTV-2 to the primed surface and cure as desired.

Nye OCK 451 is a commercial silicone sold by Nye Lubricants for electronics application. OCK 451 silicone is also a two part hydrosilation (platinum cured) cured silicone, which contains both D methyl and D phenyl groups. It has a refractive index of 1.5 at ˜590 nm, and is known for its transparency. GE Toshiba (TOS) 9142 is a two part hydrosilation cured encapsulant material available from GE Toshiba Silicones Co., Ltd.

An ethylene bond (—CH₂CH₂—) between two silicone atoms may be formed by a hydrosilylation reaction as shown below:

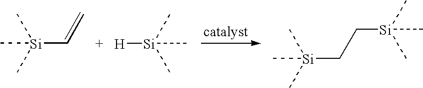

In a variety of exemplary embodiments, the hydrosilylation reaction may be carried out to prepare the 0-containing silicone of the invention, in the presence of a hydrosilylation catalyst selected from the group of ruthenium, osmium, rhodium, iridium, palladium and platinum hydrosilylation catalysts. Exemplary catalysts are those described in U.S. Pat. Nos. 2,823,218; 3,159,601; 3,159,662; and 3,775,452. Preferably, the catalysts are platinum catalysts such as platinum black, platinum chloride, chloroplatinic acid, the reaction products of chloroplatinic acid with monohydric alcohols, complexes of chloroplatinic acid with olefins, platinum bisacetoacetate, and other solubilized platinum compounds. A skilled person in the art may consult numerous prior patents and references on the usage of platinum catalyst. For example, platinum compounds having the formula (PtCl₂Olefin) and H(PtCl₃Olefin) are described in U.S. Pat. No. 3,159,601; cyclopropane complex of platinum chloride is described in U.S. Pat. No. 3,159,662; a complex formed from chloroplatinic acid with up to 2 moles per gram of platinum of a member selected from the class consisting of alcohols, ethers, aldehydes and mixtures of the above is described in U.S. Pat. No. 3,220,972. Other catalysts are described in U.S. Pat. Nos. 3,715,334; 3,775,452; and 3,814,730 to Karstedt. Additional background concerning the art may be found at J. L. Spier, “Homogeneous Catalysis of Hydrosilation by Transition Metals, in Advances in Organometallic Chemistry, volume 17, pages 407 through 447, F. G. A. Stone and R. West editors, published by the Academic Press (New York, 1979).

The platinum catalysts can be those platinum compound catalysts that are well soluble in the reaction mixture, and optical clarity of the cured composition can be obtained, for example, reaction product of H₂PtCl₆ in n-octanol.

In a variety of exemplary embodiments, the hydrosilylation reaction uses Pt catalyst. The Pt catalyst concentration in the silicone may range from 5 to 20 ppm, preferably from 10 to 15 ppm.

Optionally, the encapsulant may include various additives, for example, reinforcing inorganic fillers such as fumed silica and fumed titanium dioxide; non-reinforcing inorganic fillers such as calcium carbonate, calcium silicate, titanium dioxide, and zinc oxide; phosphors for wavelength alteration; dyes and pigments; flame retardants; and light scattering agents such as finely divided titanium oxide.

The adhesion promoter is incorporated into pre-cured silicones. In various embodiments, the amount of the adhesion promoter is generally from about 0.01% to about 20% by weight, preferably from about 0.05% to about 10% by weight, and more preferably from about 0.1% to about 3% by weight, based on the total weight of the encapsulant formulation.

In various embodiments, the adhesion promoter comprises at least one functionality selected from alkoxy, alkenoxy, epoxy, acryl, alkenyl or silicon hydride. For example, the adhesion promoter can be selected from the group consisting of alkylsilane epoxy, alkoxysilane epoxy, alkylsilane hydride, and any combination thereof.

The adhesion promoter can comprise an epoxy-functional silane, for example, the epoxy-functional silane of Formula (I):

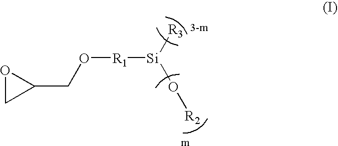

wherein R₁ is a direct bond or a C₁₆ hydrocarbon divalent group, R₂ is a C₁₋₆ hydrocarbon group, R₃ is a C₁₋₆ saturated or unsaturated hydrocarbon group, and m=1, 2, or 3. A particularly preferred epoxy-functional silane is 3-glycidoxypropyltrimethoxysilane, which corresponds to that R₁ is 1,3-propylene, R₂ is methyl, and m=3.

The adhesion promoter can comprise glycidoxytrimethoxysiloxane (I-1), which corresponds to Formula (I) in which R₁ is a direct bond, R₂ is methyl, and m=3.

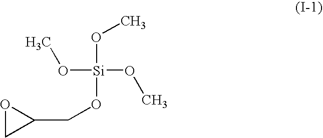

Specific examples of epoxy-functional silane include, but are not limited to, 3-glycidoxy-1,2-epoxy-4-(2-trimethoxysilylethyl)cyclohexane; 1,2-epoxy-2-methyl-4-(1-methyl-2-trimethoxysilylethyl)cyclohexane; and 1,2-epoxy-4-(2-trimethoxysilylethyl)cyclohexane etc.

Epoxy-functional silane such as bis or tris epoxy siloxanes may be used.

The following adhesion promoters and any combination thereof can be used:

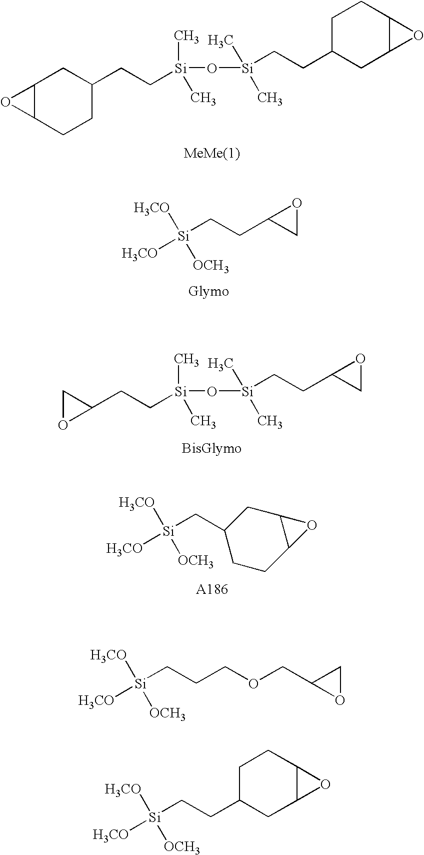

In exemplified embodiments, MeMe is 1,3-bis(1,2-epoxy-4-cyclohexylethyl)-1,1,3,3-tetramethyldisiloxane. Glymo is γ-glycidoxypropyltrimethoxysilane. Bisglymo is bis γ-glycidoxypropyltrimethoxysilane. YC9362 is a alkylsilane hydride.

Other adhesion promoters that can be optionally used include organosilicon compounds such as organosilanes and organopolysiloxanes having a silicon atom-bonded alkoxy group. Examples of the organosilicon compounds include alkoxysilanes such as tetramethoxysilane, tetraethoxysilane, dimethyldimethoxysilane, methylphenyldimethoxysilane, methylphenyldiethoxysilane, phenyltrimethoxysilane, methyltrimethoxysilane, methyltriethoxysilane, vinyltrimethoxysilane, allyltrimethoxysilane, allyltriethoxysilane, and 3-methacryloxypropyltrimethoxysilane.

The invention also provides a method of constructing an optoelectronic device such as a LED device comprising: (a) providing an optoelectronic component; and (b) applying an encapsulant comprising a silicone such as an aliphatic silicone and an adhesion promoter onto or around the optoelectronic component.

Having mixed the adhesion promoter into the silicone, it may be applied and cured onto or around the optoelectronic component. In certain embodiments the glue or a different adhesion promoter may also be applied to the surface being encapsulated. For example, a silicone “gel” is injected within an optical shell, and the “gel” completely encapsulates the LED chip and bond wire. During the manufacturing process, silicone “gel” may be placed within the optical shell after the LED chip is inserted. Once the silicone has cured, the LED chip and bond wire are integrally sealed within the optical shell.

General encapsulation techniques for solid-state devices may be employed in the present invention, such as casting, resin transfer molding and the like. After the solid-state device is enveloped in the uncured formulation, typically performed in a mold, the formulation is cured. The curing may be conducted in one or more stages using methods such as thermal, UV, electron beam techniques, or combinations thereof. For example, the formulations may be cured in two stages wherein an initial thermal or UV cure, for example, may be used to produce a partially hardened resin. This material, which is easily handled, may then be further cured using, for example, either thermal or UV techniques, to produce a material with the desired thermal performance (for example glass transition temperature (Tg) and coefficient of thermal expansion (CTE)), optical properties and moisture resistance etc. required for encapsulated solid state devices.

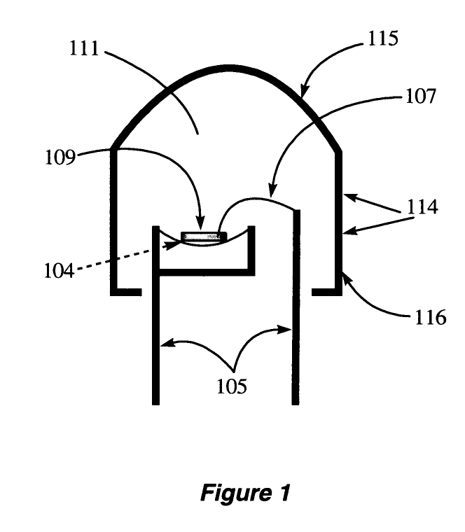

The present invention can be used in constructing a packaged solid state device that comprises (a) a package; (b) a chip; and (c) an encapsulant, as shown in FIG. 1.

With reference to FIG. 1, the figure schematically illustrates a light emitting device according to one embodiment of the present invention. The device contains a LED chip 104, which is electrically connected to a lead frame 105. For example, the LED chip 104 may be directly electrically connected to an anode or cathode electrode of the lead frame 105 and connected by a lead 107 to the opposite cathode or anode electrode of the lead frame 105, as illustrated in FIG. 1. In a particular embodiment illustrated in FIG. 1, the lead frame 105 supports the LED chip 104. However, the lead 107 may be omitted, and the LED chip 104 may straddle both electrodes of the lead frame 105 with the bottom of the LED chip 104 containing the contact layers, which contact both the anode and cathode electrode of the lead frame 105. The lead frame 105 connects to a power supply, such as a current or voltage source or to another circuit (not shown).

The LED chip 104 emits radiation from the radiation emitting surface 109. The LED may emit visible, ultraviolet or infrared radiation. The LED chip 104 may comprise any LED chip 104 containing a p-n junction of any semiconductor layers capable of emitting the desired radiation. For example, the LED chip 104 may contain any desired Group III-V compound semiconductor layers, such as GaAs, GaAlAs, GaN, InGaN, GaP, etc., or Group II-VI compound semiconductor layers such as ZnSe, ZnSSe, CdTe, etc., or Group IV-IV semiconductor layers, such as SiC. The LED chip 104 may also contain other layers, such as cladding layers, waveguide layers and contact layers.

The LED is packaged with an encapsulant 111 prepared according to the present invention. In one embodiment, the LED packaging includes encapsulant 111 located in a package, such as a shell 114. The shell 114 may be any plastic or other material, such as polycarbonate, which is transparent to the LED radiation. However, the shell 114 may be omitted to simplify processing if encapsulant 111 has sufficient toughness and rigidity to be used without a shell 114. Thus, the outer surface of encapsulant 111 would act in some embodiments as a shell 114 or package. The shell 114 contains a light or radiation emitting surface 115 above the LED chip 104 and a non-emitting surface 116 adjacent to the lead frame 105. The radiation emitting surface 115 may be curved to act as a lens and/or may be colored to act as a filter. In various embodiments the non-emitting surface 116 may be opaque to the LED radiation, and may be made of opaque materials such as metal. The shell 114 may also contain a reflector around the LED chip 104, or other components, such as resistors, etc., if desired.

In other embodiments, the encapsulant may optionally contain a phosphor to optimize the color output of the LED in FIG. 1. For example, a phosphor may be interspersed or mixed as a phosphor powder with encapsulant 111 or coated as a thin film on the LED chip 104 or coated on the inner surface of the shell 114. Any phosphor material may be used with the LED chip. For example, a yellow emitting cerium doped yttrium aluminum garnet phosphor (YAG:Ce³⁺) may be used with a blue emitting InGaN active layer LED chip to produce a visible yellow and blue light output which appears white to a human observer. Other combinations of LED chips and phosphors may be used as desired. A detailed disclosure of a UV/blue LED-Phosphor Device with efficient conversion of UV/blue Light to visible light may be found in U.S. Pat. No. 5,813,752 (Singer) and U.S. Pat. No. 5,813,753 (Vriens).

While the packaged LED chip 104 is supported by the lead frame 105 according to one embodiment as illustrated in FIG. 1, the LED can have various other structures. For example, the LED chip 104 may be supported by the bottom surface 116 of the shell 114 or by a pedestal (not shown) located on the bottom of the shell 114 instead of by the lead frame 105.

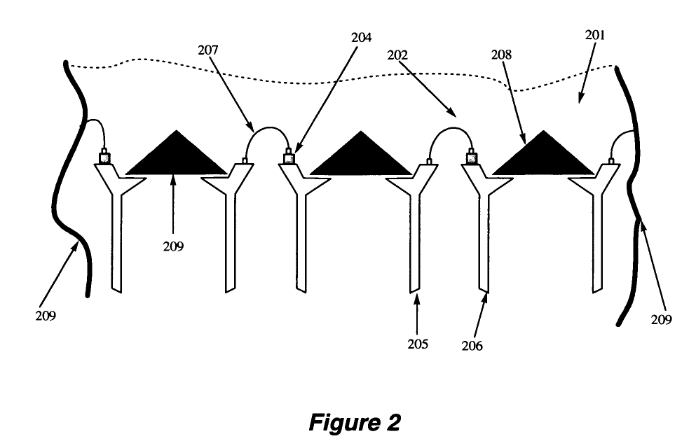

The present invention can be used in fabricating a LED array on a plastic substrate, as illustrated in FIG. 2. With reference to FIG. 2, the LED chips or die 204 are physically and electrically mounted on cathode leads 206. The top surfaces of the LED chips 204 are electrically connected to anode leads 205 with lead wires 207. The lead wires may be attached by known wire bonding techniques to a conductive chip pad. The leads 206, 205 comprise a lead frame and may be made of a metal, such as silver plated copper. The lead frame and LED chip array are contained in a plastic package 209, such as, for example, a polycarbonate package, a polyvinyl chloride package or a polyetherimide package. In some embodiments the polycarbonate comprises a bisphenol A polycarbonate. The plastic package 209 is filled with an encapsulant 201 of formulation according to the present invention. The package 209 contains tapered interior sidewalls 208, which enclose the LED chips 204, and form a light spreading cavity 202, which ensures cross fluxing of LED light.

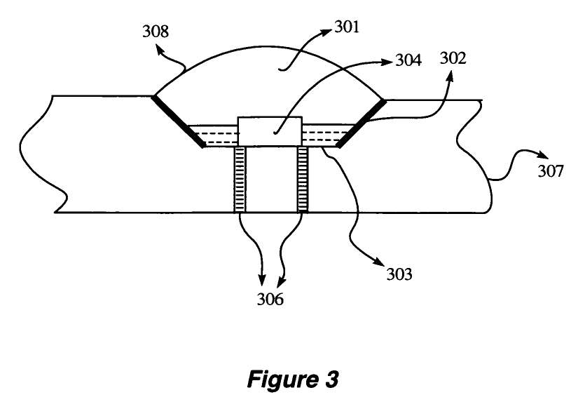

The present invention can be used in building a LED device in which the LED chip 304 is supported by a carrier substrate 307, as illustrated in FIG. 3. With reference to FIG. 3, the carrier substrate 307 comprises a lower portion of the LED package, and may comprise any material, such as plastic, metal or ceramic. Preferably, the carrier substrate is made out of plastic and contains a groove 303 in which the LED chip 304 is located. The sides of the groove 303 may be coated with a reflective metal 302, such as aluminum, which acts as a reflector. However, the LED chip 304 may be formed over a flat surface of the substrate 307. The substrate 307 contains electrodes 306 that electrically contact the contact layers of the LED chip 304. Alternatively, the electrodes 306 may be electrically connected to the LED chip 304 with one or two leads as illustrated in FIG. 3. If desired, the shell 308 or a glass plate may be formed over the encapsulant 301 to act as a lens or protective material.

The present invention may be used in constructing other semiconductor or solid state devices, for example, laser diode or other optoelectronic device chips, such as phototransistors and photodetectors. It should be understood that the method can also be used with non-light emitting chips and electronic components, for example, logic and memory devices, such as microprocessors, ASICs, DRAMs and SRAMs, as well as electronic components, such as capacitors, inductors and resistors.

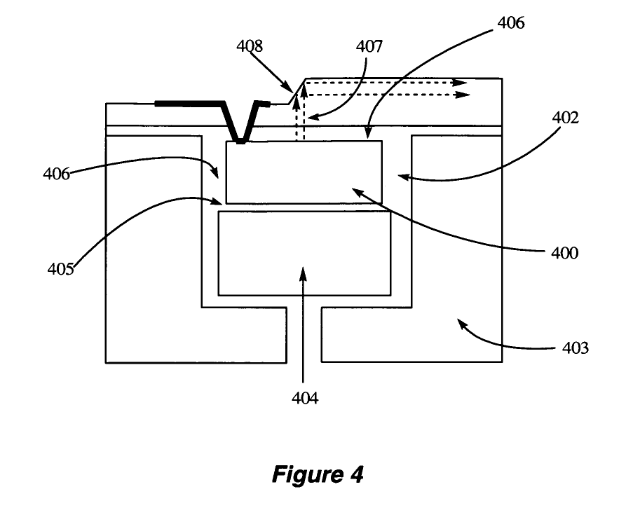

In one embodiment, the present invention is used with a vertical cavity surface emitting laser (VCSEL), as illustrated in FIG. 4. With reference to FIG. 4, the VCSEL 400 may be embedded inside a pocket 402 of a printed circuit board assembly 403. A heat sink 404 may be placed in the pocket 402 of the printed circuit board 403 and the VCSEL 400 may rest on the heat sink 404. The encapsulant 406 of the present inventive formulation may be injected into the cavity 405 of the pocket 402 in the printed circuit board 403 and may flow around the VCSEL and encapsulate it on all sides and also form a coating top film 406 on the surface of the VCSEL 400. The top coating film 406 protects the VCSEL 400 from damage and degradation and at the same time is inert to moisture and is transparent and polishable. The laser beams 407 emitting from the VCSEL may strike the mirrors 408 to be reflected out of the pocket 402 of the printed circuit board 403.

The following examples are included to provide guidance to those skilled in the art in practicing the claimed invention. The examples provided are merely representative of the work that contributes to the teaching of the present application. Accordingly, these examples are not intended to limit the invention, as defined in the appended claims, in any manner.

### EXAMPLES

### Example 1

### GE Toshiba Silicones GETOS 9142

Five different adhesion promoters, MeMe(1), A186, Glymo, BisGlymo and YC9362 were added into GETOS 9142 silicones matrix to promote the adhesion of cured silicone to the surfaces. These five promoters are siloxane-based in order for them to be miscible with silicones.

Parts A and B of silicone were mixed at a ratio of 1:1 for all adhesion strength measurements. Five promoters were added into silicone mixture with a varying ratio of 0.5, 1.0, 1.5, 2.0 and 3.0% in weight, separately. The silicones with promoter were mixed for about 2 minutes. It was prepared by a Mikrona mixer to mix part a and b (15 min RT), then the adhesion promoter was added and blended for 15 min. at RT. Part A, Part B, and promoter were mixed simultaneously, or the adhesion promoter was added to Part B or Part A and then blended the final two compositions. Silicones blended with adhesion promoters are cured within 1-2 hours at 125-150C.

ThermaLED 1, 5, and Vio™ were tested using silicones mixed with adhesion promoters at various levels listed. The devices were tested under normal operating conditions and heat, and humidity in testing was 85%@80 C. ThermaLED 1 is a high power LED device comprised of amodyl base, chip, and lens etc. ThermaLED 5 is also a power LED package with resin transfer molded epoxy lens over the chip and base. Vio™ is a high power white LED with 405 nm violet chips available from GE Lumination.

A lens/silicone adhesive/Ag coated Nickel substrate was built for Die Shear Test under ASTM D1000 or Chomerics 54. The amount of silicone mixture that was dispensed for each sandwich coupon was well controlled to keep the constant amount of mixture between each lens and substrate. A pressure of 0.25 lb was applied on the top of sample to make sure the amount of silicone adhesive between lens and substrate was even for each of them. The lens/silicone adhesive/Ag coupons were cured at 150° C. for 1 hour. The Die Shear Test was carried out at room temperature.

After die shear test, the ratio with best adhesion for each adhesion promoter was selected to make an optical sample. About 17.5 g in total for each ratio were molded into the optical glass. The optical adhesive for GETOS 9142 was cured at 150° C. for 1 hour. The aging test was carried at 125° C. for days. GretagMacbeth Color-Eye 7000A was used to measure the transmittance.

Without adding any adhesion promoter, the commercial silicone showed very weak adhesion to surfaces. GETOS 9142 shows an average value of 331.8 g.

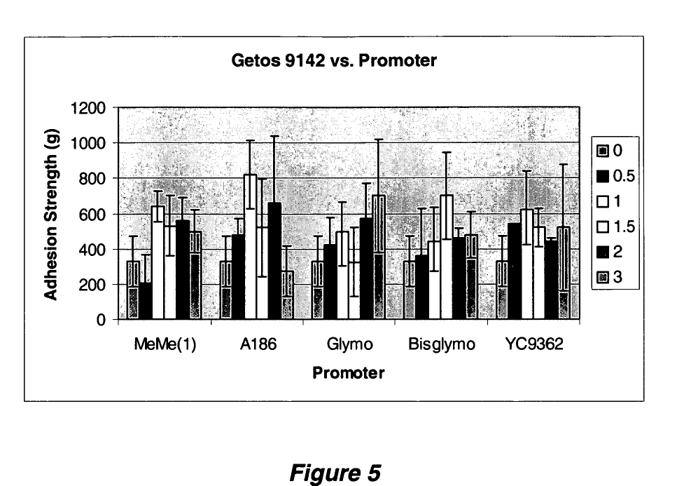

Five adhesion promoters are investigated against GE Toshiba Silicones GETOS 9142 with varying ratio of 0.5, 1.0, 1.5 2.0 and 3.0% in weight, respectively. Five die shear test measurements were made for each ratio and show in Tables 1-5. FIG. 5 shows the results of five die shear test measurements for five adhesion promoters against GETOS 9142 with varying ratio of 0.5, 1.0, 1.5 2.0 and 3.0% in weight.

TABLE 1
Getos9142-MeMe(1)

| wt % | 1 | 2 | 3 | 4 | 5 | AVG | STDEV |
|---|---|---|---|---|---|---|---|
| 0.5 | 156 | 450 | 89 | 135 | 186 | 203.2 | 142 |
| 1 | 700 | 700 | 700 | 600 | 500 | 640.0 | 89 |
| 1.5 | 500 | 600 | 250 | 600 | 700 | 530.0 | 172 |
| 2 | 500 | 500 | 500 | 500 | 800 | 560.0 | 134 |
| 3 | 400 | 400 | 500 | 700 | 500 | 500.0 | 122 |

TABLE 2
Getos9142-BisGlymo

| wt % | 1 | 2 | 3 | 4 | 5 | AVG | STDEV |
|---|---|---|---|---|---|---|---|
| 0.5 | 205 | 500 | 198 | 390 | 500 | 358.6 | 150 |
| 1 | 500 | 500 | 700 | 300 | 200 | 440.0 | 195 |
| 1.5 | 700 | 300 | 700 | 900 | 900 | 700.0 | 245 |
| 2 | 500 | 1000 | 600 | 100 | 100 | 460.0 | 378 |
| 3 | 300 | 400 | 600 | 600 | 500 | 480.0 | 130 |

TABLE 3
Getos9142-A186

| wt % | 1 | 2 | 3 | 4 | 5 | AVG | STDEV |
|---|---|---|---|---|---|---|---|
| 0.5 | 400 | 700 | 300 | 400 | 600 | 480.0 | 164 |
| 1 | 500 | 900 | 900 | 1000 | 800 | 820.0 | 192 |
| 1.5 | 200 | 600 | 300 | 900 | 600 | 520.0 | 277 |
| 2 | 400 | 700 | 400 | 800 | 1000 | 660.0 | 261 |
| 3 | 138 | 430 | 430 | 170 | 198 | 273.2 | 145 |

TABLE 4
Getos9142-YC9362

| wt % | 1 | 2 | 3 | 4 | 5 | AVG | STDEV |
|---|---|---|---|---|---|---|---|
| 0.5 | 100 | 800 | 600 | 700 | 500 | 540.0 | 270 |
| 1 | 300 | 900 | 700 | 600 | 600 | 620.0 | 217 |
| 1.5 | 400 | 400 | 600 | 600 | 600 | 520.0 | 110 |
| 2 | 300 | 700 | 500 | 200 | 500 | 440.0 | 195 |
| 3 | 100 | 900 | 200 | 800 | 600 | 520.0 | 356 |

TABLE 5
Getos9142-Glymo

| wt % | 1 | 2 | 3 | 4 | 5 | AVG | STDEV |
|---|---|---|---|---|---|---|---|
| 0.5 | 500 | 300 | 500 | 400 | 500 | 425.0 | 89 |
| 1 | 400 | 400 | 700 | 600 | 300 | 500.0 | 164 |
| 1.5 | 400 | 600 | 100 | 400 | 200 | 325.0 | 195 |
| 2 | 300 | 600 | 500 | 600 | 600 | 575.0 | 130 |
| 3 | 900 | 1200 | 700 | 400 | 500 | 700.0 | 321 |

The silicone adhesion is promoted for at least two folds for each promoter with the best ratio. For example, the best ratio in weight is 1% for MeMe(1), 1%, for Glymo 3% for A186, 1.5% for Bisglymo, and 1% for YC9362, respectively.

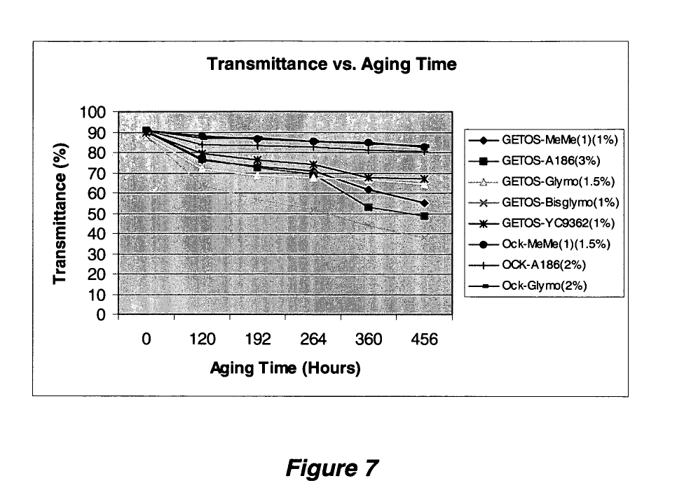

FIG. 7 shows the transmittance change of GE Toshiba GETOS 9142 and NYE OCK 451 with adhesion promoters over aging time at 125° C.

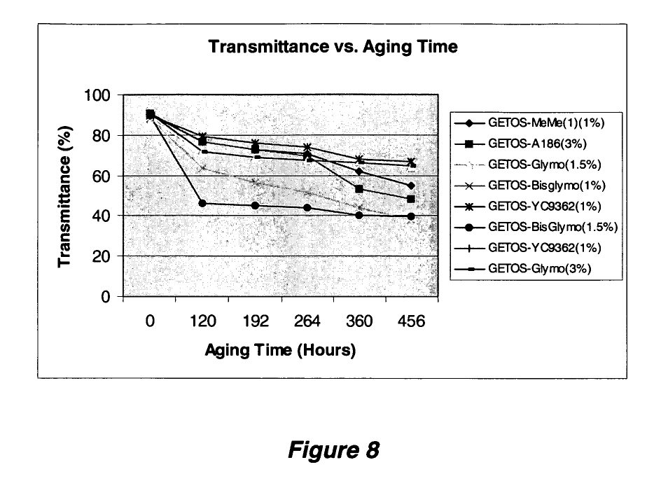

FIG. 8 shows the transmittance changes of GETOS 9142 silicone with aging time for different adhesion promoters with different level.

### Example 2

### Nye Optical's NYE OCK 451

Example 2 is similar to Example 1 except that Nye Optical's NYE OCK 451 was used as the silicones material; and the optical adhesive for NYE OCK 451 was cured at 85° C. for 1 hour.

Without adding any adhesion promoter, the commercial silicone showed very weak adhesion to surfaces. NYE OCK 451 shows a poorer adhesion that is only 23.4 g.

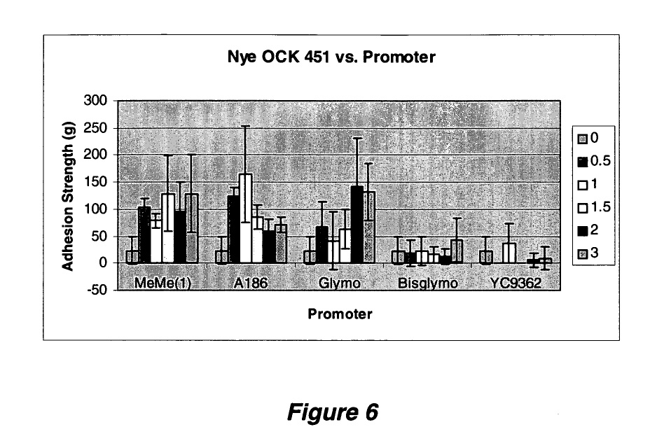

The five promoters were examined with Nye Optical's NYE OCK 451 s\as shown in Tables 6-10. FIG. 6 shows the results of five die shear test measurements for five adhesion promoters against NYE OCK 451 with varying ratio of 0.5, 1.0, 1.5 2.0 and 3.0% in weight.

TABLE 6
Nye OCK 451-MeMe(1)

| wt % | 1 | 2 | 3 | 4 | 5 | AVG | STDEV |
|---|---|---|---|---|---|---|---|
| 0.5 | 118 | 8 | 108 | 108 | 110 | 104.4 | 15 |
| 1 | 98 | 68 | 73 | 68 | 88 | 79.0 | 13 |
| 1.5 | 250 | 120 | 70 | 90 | 115 | 129.0 | 71 |
| 2 | 78 | 63 | 65 | 193 | 80 | 95.8 | 55 |
| 3 | 68 | 63 | 178 | 230 | 110 | 129.8 | 73 |

TABLE 7
Nye OCK 451-A186

| wt % | 1 | 2 | 3 | 4 | 5 | AVG | STDEV |
|---|---|---|---|---|---|---|---|
| 0.5 | 125 | 103 | 128 | 143 | 126 | 125.0 | 14 |
| 1.0 | 95 | 165 | 155 | 93 | 313 | 164.2 | 90 |
| 1.5 | 88 | 65 | 68 | 85 | 120 | 85.2 | 22 |
| 2.0 | 48 | 93 | 73 | 40 | 43 | 59.4 | 23 |
| 3.0 | 63 | 53 | 78 | 70 | 90 | 70.8 | 14 |

TABLE 8
Nye OCK 451-Glymo

| wt % | 1 | 2 | 3 | 4 | 5 | AVG | STDEV |
|---|---|---|---|---|---|---|---|
| 0.5 | 55 | 78 | 28 | 138 | 23 | 66.8 | 47 |
| 1 | 118 | 15 | 28 | 113 | 10 | 41.5 | 54 |
| 1.5 | 43 | 13 | 88 | 50 | 103 | 63.5 | 36 |
| 2 | 38 | 75 | 80 | 265 | 150 | 142.5 | 90 |
| 3 | 150 | 120 | 88 | 100 | 220 | 132.0 | 53 |

TABLE 9
Nye OCK 451-BisGlymo

| wt % | 1 | 2 | 3 | 4 | 5 | AVG | STDEV |
|---|---|---|---|---|---|---|---|
| 0.5 | 35 | 0 | 3 | 55 | 3 | 19.2 | 25 |
| 1 | 0 | 0 | 28 | 63 | 23 | 22.8 | 26 |
| 1.5 | 0 | 23 | 10 | 8 | 38 | 15.8 | 15 |
| 2 | 10 | 33 | 20 | 0 | 3 | 13.2 | 13 |
| 3 | 113 | 43 | 25 | 25 | 10 | 43.2 | 41 |

TABLE 10
Nye OCK 451-YC9362

| wt % | 1 | 2 | 3 | 4 | 5 | AVG | STDEV |
|---|---|---|---|---|---|---|---|
| 0.5 | 0 | 0 | 0 | 0 | 0 | 0.0 | 0 |
| 1 | 0 | 68 | 47 | 0 | 72 | 37.4 | 35 |
| 1.5 | 0 | 0 | 0 | 0 | 0 | 0.0 | 0 |
| 2 | 0 | 29 | 0 | 0 | 0 | 5.8 | 13 |
| 3 | 47 | 0 | 0 | 0 | 0 | 9.4 | 21 |

The adhesion of NYE OCK 451 to surfaces without additional promoters is averagely about 25 g. The addition of MeMe(1), A186 and Glymo can promote silicone adhesion by 4 to 6 folds.

FIG. 7 shows the transmittance change of GE Toshiba GETOS 9142 and NYE OCK 451 with adhesion promoters over aging time at 125° C.

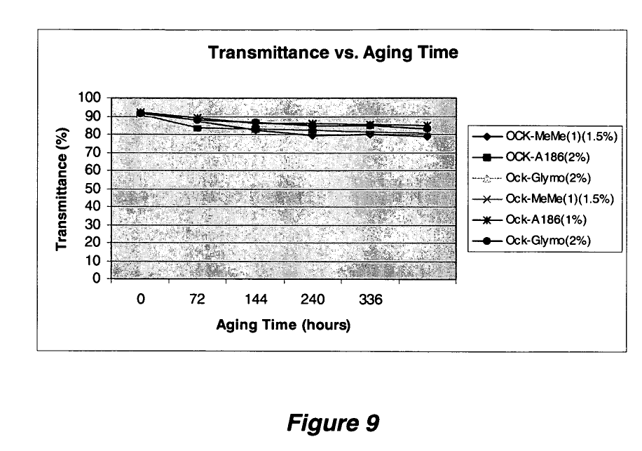

FIG. 9 shows the transmittance changes of NYE OCK 451 silicone with aging time for different adhesion promoters with different level.

Examples 1 and 2 show that GETOS 9142 has significantly better adhesion to the surface than NYE OCK 451; addition of each of five promoters at an optimal ratio increases the GETOS 9142 adhesion by approximately two fold; and addition of such promoters as MeMe(1), A186 and Glymo can promote Nye OCK 451 adhesion by 4 to 6 folds. However, it is still far below the adhesion values of GETOS 9142 obtained with the same corresponding promoters.

### Example 3

### NYE OCK 451 with Other Adhesion Promoters

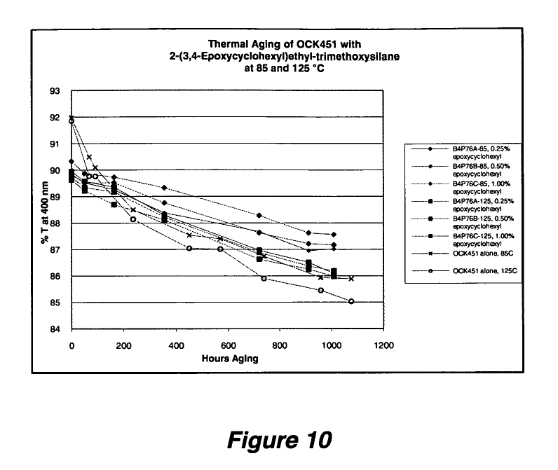

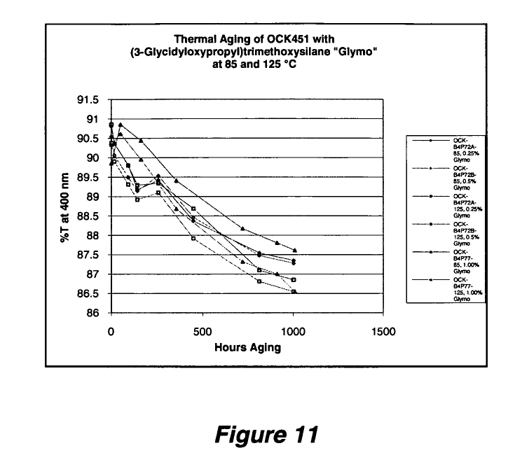

Other adhesion promoters were also tested with NYE OCK 451. FIG. 10 shows the thermal aging of NYE OCK 451 with 2-(3,4-epoxy cyclohexyl)ethyl-trimethoxysilane at 85 and 125° C. FIG. 11 shows the thermal aging of NYE OCK 451 with (3-glycidyloxypropyl)trimethoxysilane at 85 and 125° C.

### Example 4

### GE RTV 615 and 656

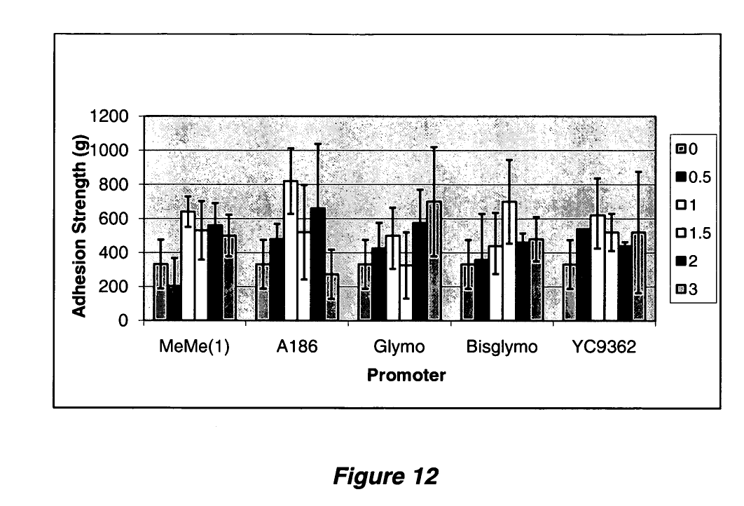

Similar to Examples 1 and 2, GE RTV 615 and 656 were also tested. FIG. 12 shows the results of five die shear test measurements for five adhesion promoters against GE RTV 615 with varying ratio of 0.5, 1.0, 1.5 2.0 and 3.0% in weight. GE RTV 656 performed comparably.

While the invention has been illustrated and described in typical embodiments, it is not intended to be limited to the details shown, since various modifications and substitutions can be made without departing in any way from the spirit of the present invention. As such, further modifications and equivalents of the invention herein disclosed may occur to persons skilled in the art using no more than routine experimentation, and all such modifications and equivalents are believed to be within the spirit and scope of the invention as defined by the following claims. All patents and publications cited herein are incorporated herein by reference.

1. An optoelectronic device including an optoelectronic component and an encapsulant, the encapsulant comprising a silicone and an adhesion promoter, wherein the optoelectronic component is at least partially surrounded by the encapsulant.

2. The optoelectronic device of claim 1, said optoelectronic component being selected from the group consisting of light emitting diodes (LEDs) and array thereof, charge coupled devices (CCDs), large scale integrations (LSIs), photodiodes, laser diodes, vertical cavity surface emitting lasers (VCSELs), phototransistors, photocouplers, and optoelectronic couplers.

3. The optoelectronic device of claim 1, wherein the optoelectronic component comprises a semiconductor chip and at least one of lead frame, bond wire, solder, electrode, pad, contact layer, phosphor layer, dielectric layer, receptacle, silver substrate, and electrical board.

4. The optoelectronic device of claim 1, wherein the optoelectronic component is comprised of one of metal; silicon; silicon dioxide; silicon nitride; aluminum nitride; alumina; fluorocarbon polymers; polyamide; polyimide; silicone; epoxy resin; polyesters; ceramics; plastic; or glass.

5. The optoelectronic device of claim 1, wherein the adhesion promoter comprises at least one functionality selected from alkoxy, alkenoxy, epoxy, acryl, alkenyl or silicon hydride.

6. The optoelectronic device of claim 1, wherein the adhesion promoter is selected from the group consisting of alkylsilane epoxy, alkoxysilane epoxy, alkylsilane hydride, and any combination thereof.

7. The optoelectronic device of claim 1, wherein the adhesion promoter is selected from the following compounds or their mixture:

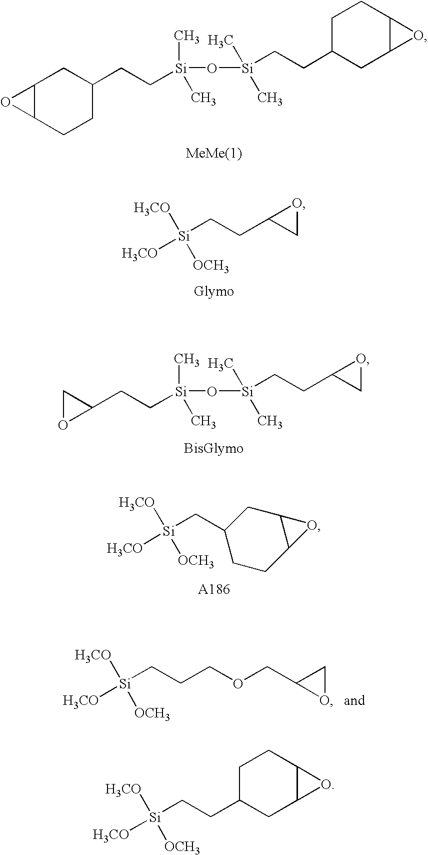

8. The optoelectronic device of claim 1, wherein the adhesion promoter comprises an epoxy-functional silane represented by Formula (I): 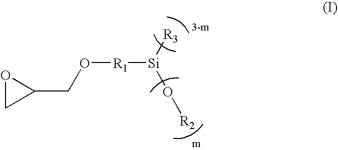
wherein R₁ is a direct bond or a C₁₋₆ hydrocarbon divalent group, R₂ is a C₁₋₆ hydrocarbon group, R₃ is a C₁₋₆ saturated or unsaturated hydrocarbon group, and m=1, 2, or 3.

9. The optoelectronic device of claim 8, wherein R₁ is a direct bond, R₂ is methyl, and m=3.

10. The optoelectronic device of claim 1, wherein the amount of the adhesion promoter is from about 0.01% to about 20% by weight based on the total weight of the encapsulant formulation.

11. The optoelectronic device of claim 11, wherein the amount of the adhesion promoter is from about 0.05% to about 10% by weight based on the total weight of the encapsulant formulation.

12. The optoelectronic device of claim 1, wherein the silicone comprises an aliphatic silicone.

13. The optoelectronic device of claim 12, wherein the silicone comprises aliphatic silicone, copolymer of aliphatic silicone and other polymer such as epoxy resin, copolymer of aliphatic silicone and aromatic silicone, or mixture thereof.

14. The optoelectronic device of claim 12, wherein the aliphatic group in the aliphatic silicone is selected from alkyl groups, such as C₁-C₆ alkyl groups.

15. The optoelectronic device of claim 13, wherein the alkyl group is methyl group.

16. The optoelectronic device of claim 1, wherein the aliphatic silicone is prepared from a RTV-2 silicone system based on hydrosilylation reaction.

17. A method of constructing an optoelectronic device such as a LED device comprising: (a) providing an optoelectronic component; and (b) applying an encapsulant comprising a silicone containing an adhesion promoter onto or around the optoelectronic component.

18. The method of claim 17, wherein the optoelectronic component comprises a board, the encapsulant comprises a RTV-2 silicone; and the adhesion promoter is selected from the following compounds or their mixture: [chemical structure]
